(19) United States
(12) Patent Application Publication
(10) Pub. No.: US 2026/0090070 A1
(43) Pub. Date: Mar. 26, 2026

(54) SEMICONDUCTOR STRUCTURES WITH ROUTING PATH IN DUMMY REGION

(71) Applicant: Taiwan Semiconductor Manufacturing Company, Ltd., Hsinchu (TW)

(72) Inventors: Yi-Hui Chen, Changhua City (TW); Yi-Lii Huang, Zhubei City (TW); Jung-You Chen, Zhubei City (TW); Chih-Hsiao Chen, Taichung City (TW); Hui-Hsuan Kung, Taichung City (TW); Yi-Chen Li, Taichung City (TW)

(73) Assignee: Taiwan Semiconductor Manufacturing Company, Ltd., Hsinchu (TW)

(21) Appl. No.: 18/891,624

(22) Filed: Sep. 20, 2024

(51) Int. Cl. H01L 21/8234; H01L 27/088; H01L 29/06; H01L 29/08; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 62/151; H10D 84/0149; H10D 84/83

(57) ABSTRACT

Semiconductor structures and methods of fabrication are provided. A semiconductor structure includes a substrate comprising a device region and a dummy region; transistor devices disposed in the device region and respectively comprising source/drain features disposed on opposing sides of a first gate structure; dummy transistor devices disposed in the dummy device region and respectively comprising dummy source/drain features disposed on opposing sides of a second gate structure; and a conductive path formed by a conductive structure or conductive structures directly over and isolated from the dummy transistor devices in the dummy region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an overhead schematic view illustrating an integrated chip structure having device regions and dummy regions according to some embodiments;

FIG. 2 is a flow chart illustrating a method for forming the integrated chip structure having device regions and dummy regions of FIG. 1, according to some embodiments;

FIGS. 3-10 are cross-sectional X-cut schematic views illustrating successive stages of fabrication of the integrated chip structure having device regions and dummy regions of FIG. 1 according to some embodiments; and

FIGS. 11-19 are cross-sectional X-cut schematic views, at the stage of fabrication of FIG. 10, of alternative structures according to some embodiments.

FIG. 20 is a cross-sectional X-cut schematic view, at the stage of fabrication of FIG. 10, of multiple dummy devices and conductive paths overlying the dummy devices in a dummy region according to some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 100 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 100 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 100 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of a conductive routing or conductive paths formed over and isolated from devices in a dummy region. For example, such conductive paths may be formed during middle-end-of-line (MEOL) processing.

In embodiments herein, a desired resistance of a conductive path or paths may be determined, and then conductive structures are designed and fabricated to form the conductive path or paths with the desired resistance. In certain embodiments, a selective contact etch stop layer is formed over dummy regions and is not formed or is removed from over device regions. In such embodiments, the selective contact etch stop layer isolates the underlying dummy device or dummy devices from the overlying conductive path or conductive paths.

In other embodiments, a dielectric layer, such as an interlayer dielectric (ILD), is formed over both the dummy regions and over the device regions. Conductive contacts are formed through the dielectric layer to contact the devices in the device regions. In the dummy regions, the dielectric layer or (ILD) remains over the devices in the dummy regions. Then conductive vias may be formed over both the dummy regions and over the device regions. In the dummy regions, the remaining dielectric layer isolates the conductive vias from the underling dummy devices. In the device regions, the conductive vias are electrically connected to the devices by the conductive contacts.

Embodiments of the present disclosure offer advantages over the existing art, though it is understood that other embodiments may offer different advantages, not all advantages are necessarily discussed herein, and no particular advantage is required for all embodiments.

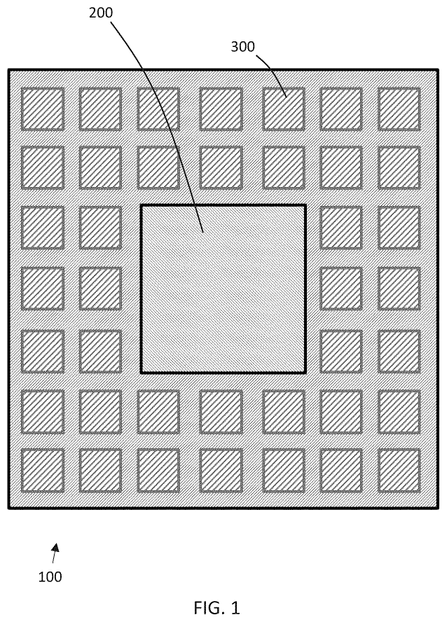

Referring now to FIG. 1, an overhead view illustrates an integrated chip structure 100 having device regions 200 and dummy regions 300 according to some embodiments.

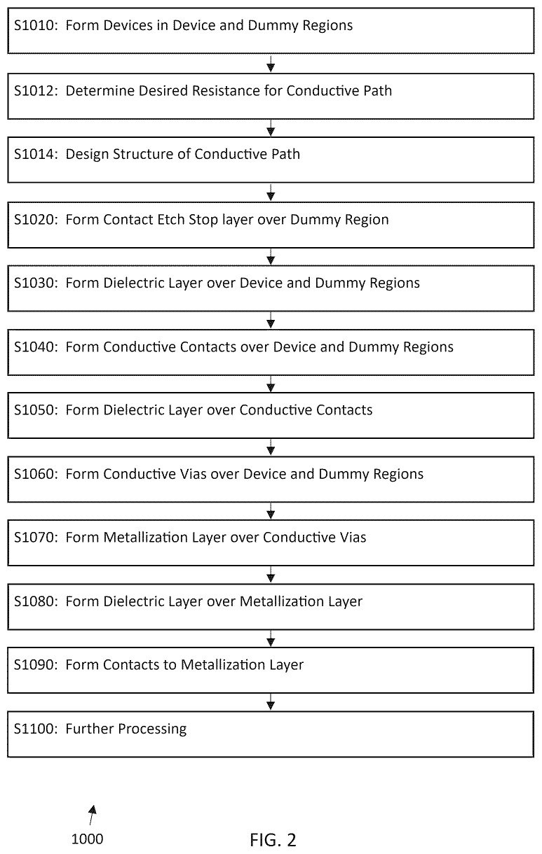

FIG. 2 is a flow chart illustrating a method for forming the integrated chip structure 100 having device regions 200 and dummy regions 300 of FIG. 1 according to some embodiments.

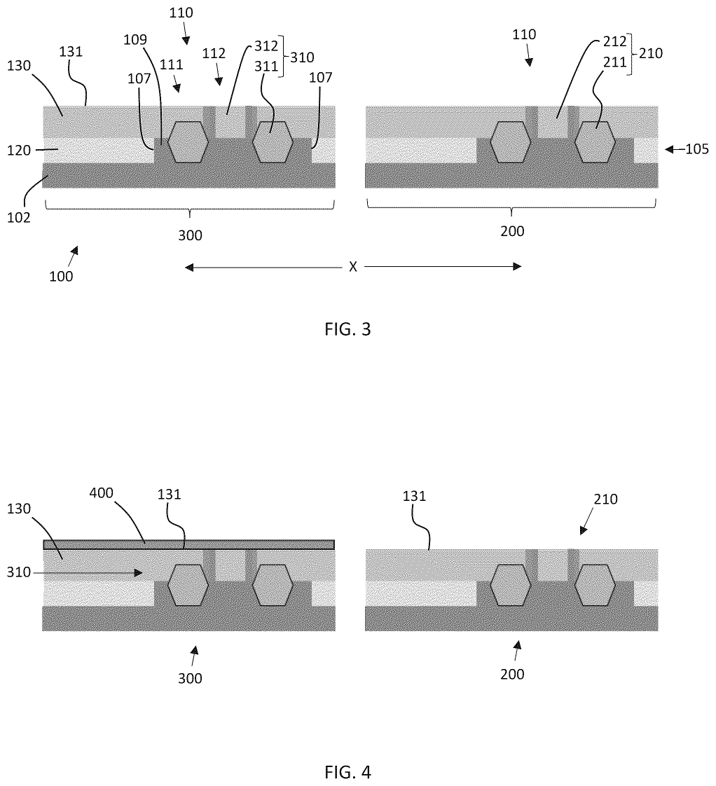

FIGS. 3-10 are cross-sectional schematic views illustrating successive stages of fabrication of the integrated chip structure 100 having device regions 200 and dummy regions 300 of FIG. 1 according to some embodiments. Each cross-sectional view herein is an X-cut, i.e., a view taken along an X-axis.

Cross-referencing FIGS. 1-3, method 1000 includes, at S1010, forming devices 110, including device 210 and 310, in device regions 200 and dummy regions 300. Specifically, devices 210 are formed in device region 200 and dummy devices 310 are formed in dummy regions 300. Operation S1010 may include front-end-of-line (FEOL) processing.

The devices 110 may include P-type metal-oxide-semiconductor devices and/or N-type metal-oxide-semiconductor devices. The devices 110 may be planar semiconductor devices; FinFET devices, i.e., devices with fin-like structures; gate-all-around (GAA) devices including any device that has its gate structure, or portion thereof, formed on four sides of a channel region (e.g., surrounding a portion of a channel region); or another type of multi-gate devices. Devices 110 presented herein also include embodiments that have channel regions disposed in nanosheet channel(s), nanowire channel(s), bar-shaped channel(s), and/or other suitable channel configurations.

Operation S1010 may include providing a substrate 102. In some embodiments, the substrate 102 may be a semiconductor substrate such as a silicon substrate. The substrate 102 may include various layers, including conductive or insulating layers formed on a semiconductor substrate. The substrate 102 may include various doping configurations depending on design requirements as is known in the art. The substrate 102 may also include other semiconductors such as germanium, silicon carbide (SiC), silicon germanium (SiGe), or diamond. Alternatively, the substrate 102 may include a compound semiconductor and/or an alloy semiconductor. Further, the substrate 102 may optionally include an epi layer, may be strained for performance enhancement, may include a silicon-on-insulator (SOI) structure, and/or have other suitable enhancement features.

Operation S1010 may include forming structures 109 from the substrate 102. For example, fin structures 109 may be formed from substrate 102. In embodiments in which the devices 110 are GAA devices, a stack of layers may first be formed over the substrate 102 before formation of the active structures 109. In FIG. 3, parallel active structures 109 extend in the X-direction between ends 107 and are separated from one another in a Y-direction (perpendicular to the drawing sheet). Trenches are defined between adjacent fin structures 109 and at the ends 107 of fin structures 109.

Operation S1010 may further include forming shallow trench isolation (STI) features 120 around the fin structures 109. The STI features 120 may be formed by first filling the trenches around each fin structure 109 with a dielectric material layer to cover top surfaces and sidewalls of the fin structure 109 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of an overlying mask layer are revealed, and the dielectric material layer is recessed to form the STI features 120. Any suitable etching technique may be used to recess the isolation features including dry etching, wet etching, RIE, and/or other etching methods, and in an exemplary embodiment, an anisotropic dry etching is used to selectively remove the dielectric material of the isolation features without etching the fin structure 109.

Operation S1010 may further include forming sacrificial gate structures (not shown). The sacrificial gate structures are formed over portions of the fin structure 109 which are to be channel regions. The sacrificial gate structures may extend over a number of adjacent fins 109. The sacrificial gate structures lie directly over and define the channel regions of the devices to be formed. Each of the sacrificial gate structures includes a sacrificial gate dielectric and a sacrificial gate electrode over the sacrificial gate dielectric. The sacrificial gate structures extend lengthwise in the Y-direction and are spaced apart in the X-direction.

Operation S1010 may further include forming spacers on sidewalls of the sacrificial gate structures and on sidewalls of the fin structures 109 by depositing spacer materials, followed by an etching. The spacers may include spacer material such as silicon oxide, silicon nitride, silicon carbide, silicon oxynitride, SiCN films, silicon oxycarbide, SiOCN films, and/or combinations thereof. In some embodiments, each of the spacers include multiple layers, such as a liner layer and a main spacer layer on a sidewall of the liner layer.

By way of example, the spacers may be formed by depositing spacer material including a liner material layer and a dielectric material layer over the sacrificial gate structure using processes such as a subatmospheric CVD (SACVD) process, a flowable CVD process, an ALD process, a PVD process, or other suitable process respectively.

Operation S1010 may further include forming source/drain features 111, including source/drain features 211 in region 200 and source/drain features 311 in region 300. As used herein, “source/drain feature(s)” may refer to a source feature or a drain feature, individually or collectively depending on the context. The source/drain features 111 may be formed by etching the fin structures 109 on either side of the overlying sacrificial gate structure to form trenches, and growing epitaxial material in the trenches. Alternatively, source/drain features 111 may be formed by implantation processes.

For GAA devices, operation S1010 may further include recessing of epitaxial layers forming nanosheets and forming inner spacers before forming source/drain features 111.

In exemplary embodiments, the source/drain features 111 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

Operation S1010 may further include capping the source/drain features 111 with a dielectric layer 130. Specifically, a dielectric liner may be formed over source/drain features 111 and along the sides of the spacers. Further, a dielectric layer 130 may be formed over the liner over the source/drain features 111. In exemplary embodiments, the dielectric layer 130 is a bottom interlayer dielectric layer (ILD0). The dielectric layer 130 may be silicon oxide or other suitable dielectric material. In certain embodiments, the dielectric liner is a dielectric, such as silicon nitride or another suitable material.

Operation S1010 may further include opening and removing the sacrificial gate structures. Specifically, a chemical mechanical planarization (CMP) process may be performed to uncover the sacrificial gate electrodes. Further, the sacrificial gate electrodes are removed to form gate cavities.

For GAA devices, operation S1010 may further include removing the epitaxial layers separating the nanosheet structures.

Operation S1010 may further include completing a replacement metal gate process to form gate structures 112, including gate structures 212 in regions 200 and gate structures 312 in regions 300. In exemplary embodiments, the replacement metal gate process includes forming a gate dielectric layer in the gate cavities, and forming a gate electrode material over the gate dielectric layer to fill the gate cavities. An exemplary gate dielectric layer(s) is deposited conformally in the gate cavities.

For GAA devices, the gate dielectric may be formed on the semiconductor nanosheets, and the gate electrode material may be formed on the gate dielectric layer(s). Thus, each semiconductor nanosheet is wrapped in gate dielectric and surrounded by gate electrode material.

In accordance with some embodiments, the gate dielectric layer(s) comprises silicon oxide, silicon nitride, or multilayers thereof. In some embodiments, the gate dielectric layer(s) is a high-k dielectric material, and in these embodiments, the gate dielectric layer(s) may have a k value greater than about 7.0, and may include a metal oxide or a silicate of Hf, Al, Zr, La, Mg, Ba, Ti, Pb, and combinations thereof. The formation methods of the gate dielectric layer(s) may include Molecular-Beam Deposition (MBD), ALD, PECVD, and the like.

The gate electrode material may be deposited over the gate dielectric layer(s) and fill the gate cavities. The gate electrode material may be a metal-containing material such as TiN, TaN, TaC, Co, Ru, Al, combinations thereof, or multi-layers thereof. For example, although a single gate electrode material is illustrated, any number of work function tuning layers may be deposited.

The replacement metal gate process may further include removing excess portions of the gate dielectric layer(s) and the gate electrode material located over the top surface of the ILD 130. For example, a planarization process, such as a CMP process, may be performed to remove the excess portions of the gate dielectric layer(s) and the gate electrode material. As a result, the structure 100 has an upper surface 131. The remaining portions of material of the gate dielectric layer(s) and the gate electrode material thus form the replacement gate structure 112 of the resulting devices 110. The gate dielectric layer(s) and gate electrode material may be collectively referred to as a “gate,” a “gate stack,” or a “gate structure.”

Method 1000 may further include, at operation S1012, determining a desired resistance for a selected number of conductive paths on the integrated chip structure 100.

Also, method 1000 may include, at operation S1014, designing a structure of a conductive path having the desired resistance.

Cross-referencing FIGS. 2 and 4, method 1000 may further include, at operation S1020, forming a contact etch stop layer (CESL) 400 over the dummy region 300. For example, the contact etch stop layer 400 may be formed on the surface 131 in regions 300. In certain embodiments, the contact etch stop layer 400 is a nitride-rich layer. For example, contact etch stop layer 400 may be formed from silicon nitride. As shown, the contact etch stop layer 400 is not formed over device region 200.

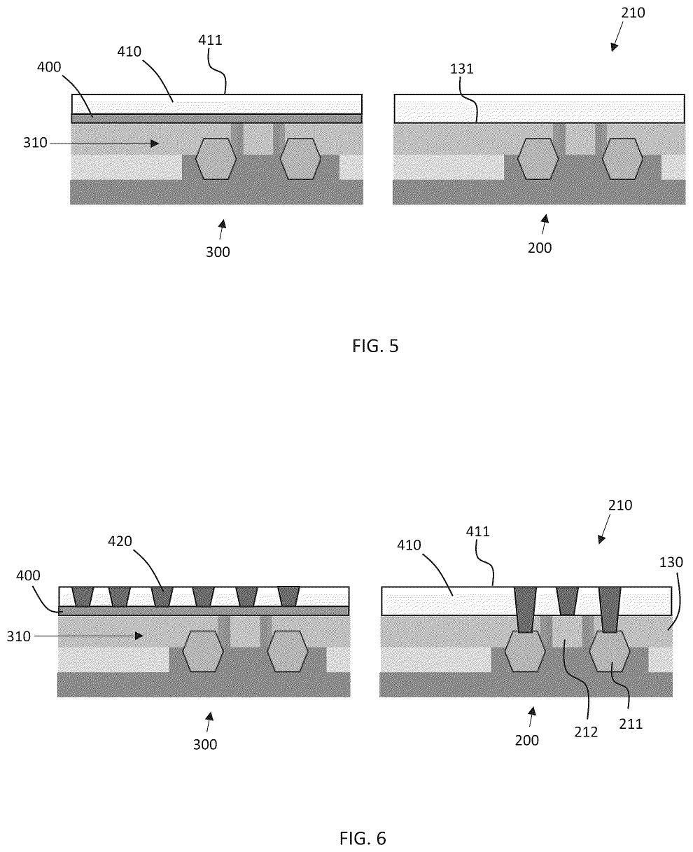

Cross-referencing FIGS. 2 and 5, method 1000 may further include, at operation S1030, forming a dielectric layer 410 over the regions 200 and 300. For example, in regions 200, the dielectric layer 410 is formed on the upper surface 131. In regions 300, the dielectric layer 410 is formed on the contact etch stop layer 400.

In exemplary embodiments, the dielectric layer 410 is a next interlayer dielectric layer (ILD1). The dielectric layer 410 may be silicon oxide or other suitable dielectric material.

A planarization process may be performed to define the dielectric layer 410 with an upper surface 411. In certain embodiments, the upper surface 411 of the dielectric layer 410 is co-planar across regions 200 and 300.

Cross-referencing FIGS. 2 and 6, method 1000 may further include, at operation S1040, forming contacts 420 in regions 200 and 300. Operation S1040 may include etching openings in the dielectric layer 410 where contacts 420 are to be formed. As shown in FIG. 6, the etching process lands on and stops at the etch stop layer 400 in regions 300. In regions 200, the etching process, which may include one or more etching steps, may continue into contact with the gates 212 or continue through dielectric layer 130 and into contact with source/drain regions 211.

In certain embodiments, operation S1040 may include forming silicide in the trenches over source/drain features 211 in regions 200. Specifically, a silicide process may be performed to convert an upper portion of the source/drain features 211 to silicide. For example, a metal may be deposited in the trench and a thermal process may be performed to form the silicide.

Operation S1040 further includes depositing a conductive material or materials, such as a metal, over regions 200 and 300. In certain embodiments, the conductive material(s) include metal(s), such as tungsten (W) or other suitable materials. A planarization process may be performed to remove overburden portions of the conductive material from over surfaces 411. Operation S1040 may form conductive contacts 420 to source/drain features 211 and to metal gates 212 in regions 200. In dummy regions 300, the conductive contacts 420 are formed over, and are isolated by, the contact etch stop layer 400.

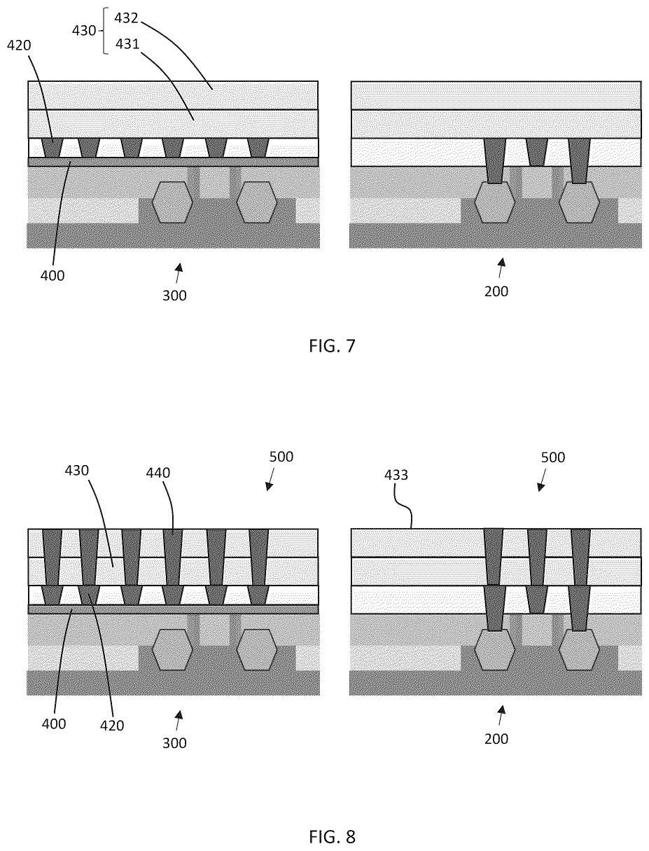

Cross-referencing FIGS. 2 and 7, method 1000 may continue at operation S1050 with depositing an additional dielectric layer 430 over regions 200 and 300. In certain embodiments, additional dielectric layer 430 may include separate layers 431 and 432. The dielectric layer 430 or layers 431 and 432 may be silicon oxide or other suitable dielectric material.

Cross-referencing FIGS. 2 and 8, method 1000 may continue at operation S1060 with forming conductive vias 440 in regions 200 and 300.

Operation S1060 may include etching openings in the dielectric layer or layers 430 where conductive vias 440 are to be formed. As shown in FIG. 8, the etching process may land on and stop at contacts 420.

Further, operation S1060 may include depositing a conductive material or materials, such as a metal, over regions 200 and 300. In certain embodiments, the conductive material(s) include metal(s), such as tungsten (W) or other suitable materials. A planarization process may be performed to remove overburden portions of the conductive material from over surfaces 433. Operation S1040 may form conductive vias 440 in selected patterns of electrical connection to conductive contacts 420 connected to source/drain features 211 and to metal gates 212 in regions 200. In dummy regions 300, the conductive vias 440 are isolated from the underlying devices 310, such as those formed during front end-of-line (FEOL) processing, by the contact etch stop layer 400.

Operations S1030-S1060 may be performed according to a design layout to form conductive paths 500 having a desired routing through selected conductive contacts 420 and/or conductive vias 440.

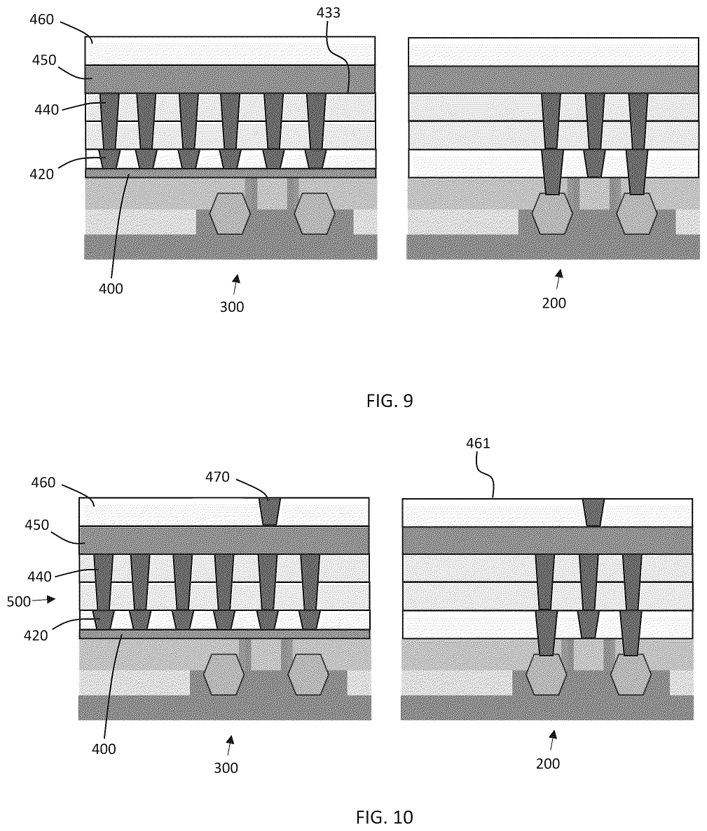

Cross-referencing FIGS. 2 and 9, method 1000 may continue at operation S1070 with forming a metallization layer 450 over surface 433 and in electrical contact with conductive vias 440 in regions 200 and 300. Metallization 450 may be formed from tungsten, aluminum, copper, or another suitable metal.

Cross-referencing FIGS. 2 and 9, method 1000 may continue at operation S1080 with forming a dielectric layer 460 over metallization layer 450 in regions 200 and 300. Dielectric layer 460 may be formed from silicon oxide or another suitable dielectric material.

Cross-referencing FIGS. 2 and 10, method 1000 may continue at operation S1090 with forming contacts 470 in regions 200 and 300. Operation S1090 may include etching openings in the dielectric layer 460 where contacts 470 are to be formed. As shown in FIG. 10, the etching process lands on and stops at the metallization layer 450.

Operation S1090 further includes depositing a conductive material or materials, such as a metal, over regions 200 and 300. In certain embodiments, the conductive material(s) include metal(s), such as tungsten (W) or other suitable materials. A planarization process may be performed to remove overburden portions of the conductive material from over surfaces 461.

Method 1000 may include further processing at operation S1100. The further processing may include other back end of line (BEOL) processes such as passivation and packaging.

Method 1000 forms a conductive path 500 having the structure designed at operation S1014 and having the desired resistance determined at operation S1012.

In FIG. 10, six routing conductive paths 500 are formed over the dummy region 300 and three routing conductive paths 500 are formed over the device region 200.

FIGS. 2-10 illustrate successive fabrication operations for simultaneously forming conductive paths 500 selectively electrically connected to devices 210 in device region 200 and conductive paths 500 that are isolated from devices 310 in dummy region 300. As a result, a structure 100 may be formed with desired electrical connection paths or routing directly over and isolated from dummy devices 310 in dummy regions 300.

In the embodiment of FIGS. 2-10, a contact etch stop layer 400 is formed over the device 310 in dummy region 300; six conductive contacts 420 are formed over the contact etch stop layer 400; and six conductive vias 440 are formed over the six conductive contacts 420 in order to form the six conductive paths 500 over the dummy region 300 and under the metallization layer 450. However, embodiments herein are not so limited.

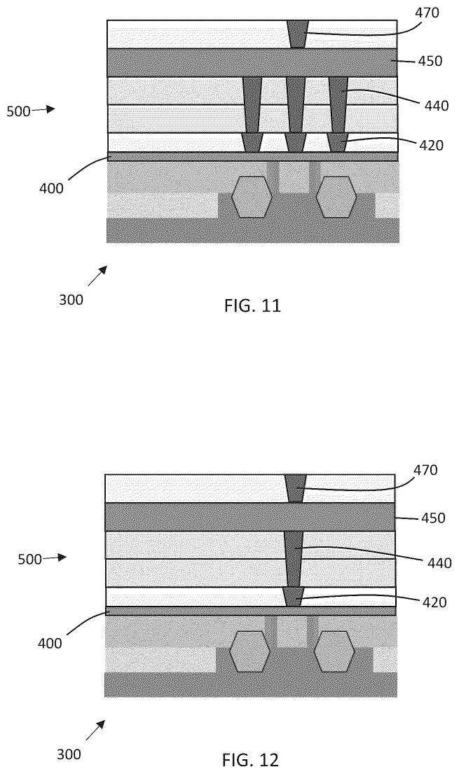

For example, FIGS. 11-19 illustrate alternative embodiments of the conductive paths 500 formed over the dummy region 300.

In FIG. 11, a contact etch stop layer 400 is formed over the device 310 in dummy region 300; three conductive contacts 420 are formed over the contact etch stop layer 400; and three conductive vias 440 are formed over the three conductive contacts 420 in order to form three conductive paths 500 over the dummy region 300 and under the metallization layer 450.

In FIG. 12, a contact etch stop layer 400 is formed over the device 310 in dummy region 300; one conductive contact 420 is formed over the contact etch stop layer 400; and one conductive via 440 is formed over the conductive contact 420 in order to form one conductive path 500 over the dummy region 300 and under the metallization layer 450.

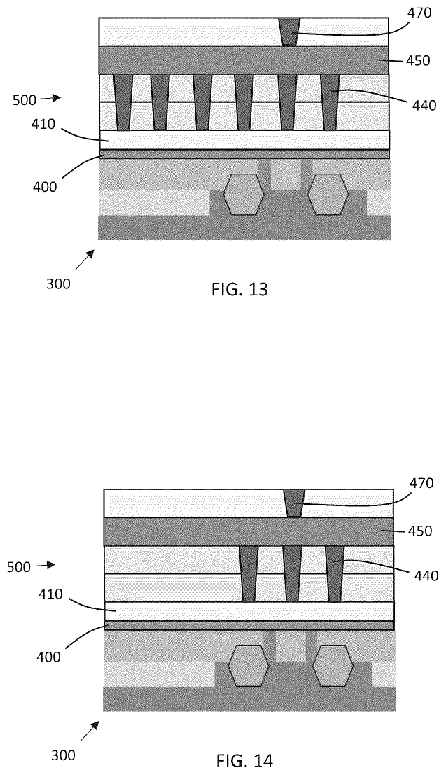

In FIG. 13, a contact etch stop layer 400 is formed over the device 310 in dummy region 300; no conductive contacts 420 are formed in the dielectric layer 410 over the contact etch stop layer 400; and six conductive vias 440 are formed over the dielectric layer 410 in order to form six conductive paths 500 over the dummy region 300 and under the metallization layer 450.

In FIG. 14, a contact etch stop layer 400 is formed over the device 310 in dummy region 300; no conductive contacts 420 are formed in the dielectric layer 410 over the contact etch stop layer 400; and three conductive vias 440 are formed over the dielectric layer 410 in order to form three conductive paths 500 over the dummy region 300 and under the metallization layer 450.

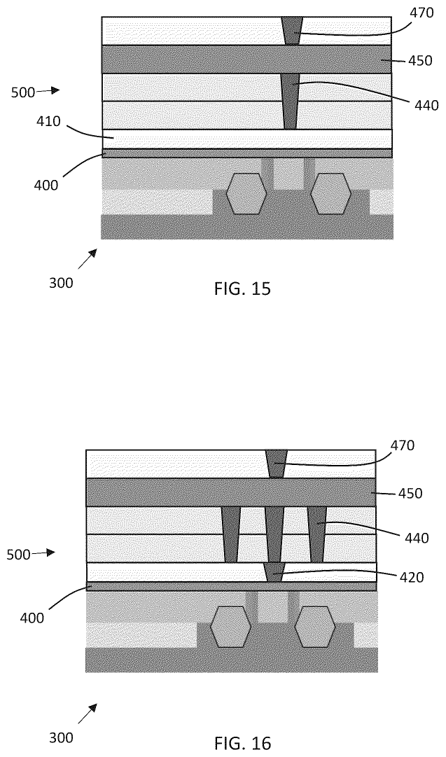

In FIG. 15, a contact etch stop layer 400 is formed over the device 310 in dummy region 300; no conductive contacts 420 are formed in the dielectric layer 410 over the contact etch stop layer 400; and one conductive via 440 is formed over the dielectric layer 410 in order to form one conductive path 500 over the dummy region 300 and under the metallization layer 450.

In FIG. 16, a contact etch stop layer 400 is formed over the device 310 in dummy region 300; one conductive contact 420 is formed in the dielectric layer 410 over the contact etch stop layer 400; and three conductive vias 440 are formed over the conductive contact 420 and dielectric layer 410 in order to form three conductive paths 500 over the dummy region 300 and under the metallization layer 450. The conductive path 500 formed by a conductive contact 420 and conductive via 440 has a different resistance as compared to the two conductive paths 500 formed only by a conductive via 440.

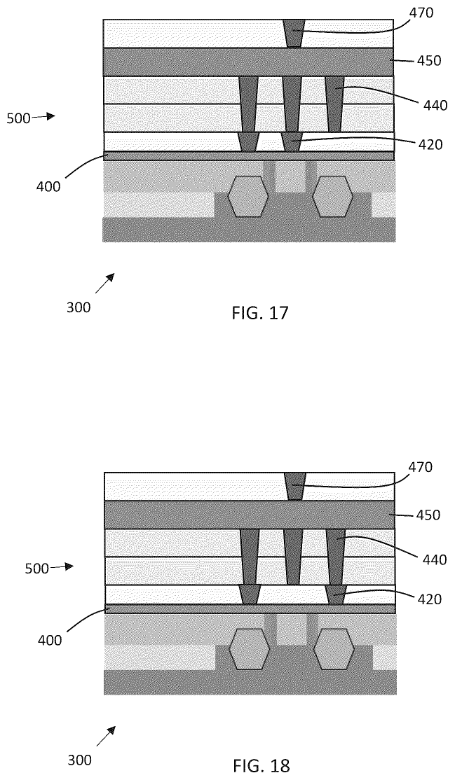

In FIGS. 17 and 18, a contact etch stop layer 400 is formed over the device 310 in dummy region 300; two conductive contacts 420 are formed in the dielectric layer 410 over the contact etch stop layer 400; and three conductive vias 440 are formed over the conductive contact 420 and dielectric layer 410 in order to form three conductive paths 500 over the dummy region 300 and under the metallization layer 450. Again, conductive paths 500 formed by a conductive contact 420 and conductive via 440 have a different resistance as compared to a conductive path 500 formed only by a conductive via 440.

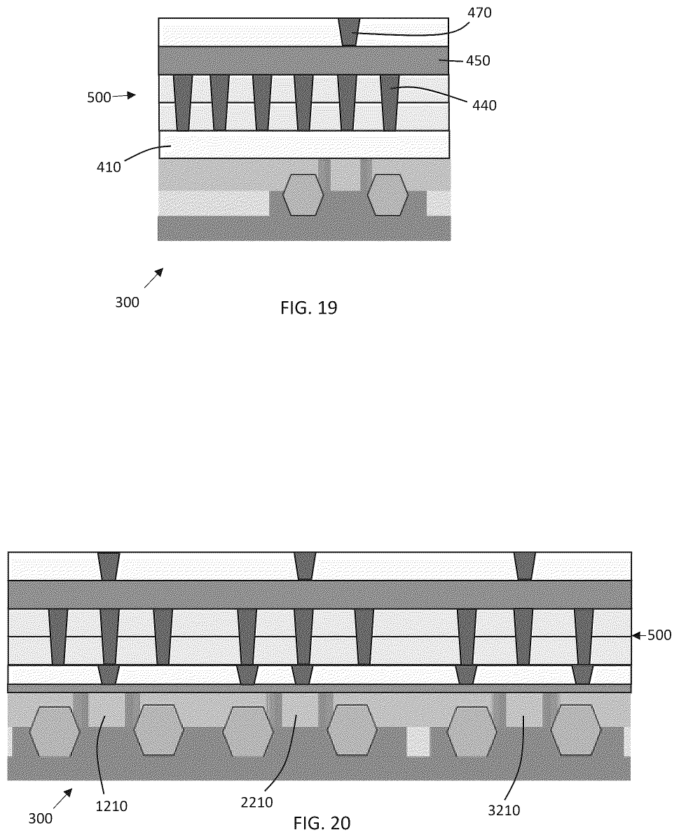

In FIG. 19, no contact etch stop layer 400 is formed over the device 310 in dummy region 300; no conductive contacts 420 are formed in the dielectric layer 410; and six conductive vias 440 are formed over the dielectric layer 410 in order to form six conductive paths 500 over the dummy region 300 and under the metallization layer 450.

Cross-referencing FIGS. 10-19, any layout may be designed in order to provide a desired number of conductive paths 500 over the dummy region 300 and under the metallization layer 450 with a desired resistance, provided that the conductive paths 500 are isolated from the underlying device or devices 310. For example, the resistance of the conductive paths 500 may be increased or decreased by adding or subtracting the number of conductive features utilized in the conductive paths 500. The contact etch stop layer 400 may be located under the conductive paths 500 to isolate the conductive paths 500 from the device or devices 310 in dummy region 300, or in embodiments in which the contact etch stop layer 400 is not present, the dielectric layer 410 may isolate the conductive paths 500 from the device or devices 310 in dummy region 300.

Thus, embodiments herein may include a dummy region 300 with or without a contact etch stop layer 400.

Embodiments herein may include a dummy region 300 with or without conductive contacts 420. In embodiments in which conductive contacts 420 are present, any desired number of conductive contacts 420 may be formed in the dummy region 300, such as from one to six, or more.

Embodiments herein may include a dummy region 300 with or without conductive vias 440. In embodiments in which conductive vias 440 are present, any desired number of conductive vias 440 may be formed in the dummy region 300, such as from one to six, or more.

The numbers and location of conductive contacts 420 and conductive vias 440 may be selected and formed in the dummy region 300 to define an electrical path with a desired resistance. In certain embodiments, conductive contacts 420 and conductive vias 440 formed in the dummy region 300 are electrically connected to devices 210 formed in the device region 200.

Further, different arrangements of conductive paths may be provided over devices 310 in a dummy region 300.

For example, in FIG. 20, dummy devices 310 including a first dummy device 1210, second dummy device 2210, and third dummy device 3210 are located in a dummy region 300. Three conductive paths 500 are formed over the first dummy device 1210, three conductive paths 500 are formed over the second dummy device 2210, and three conductive paths 500 are formed over the third dummy device 3210. A different arrangement of conductive paths 500 is provided over each dummy device 310, allowing for designing for use with different resistances.

In an embodiment, a semiconductor structure is provided and includes a substrate including a device region and a dummy region; transistor devices disposed in the device region and respectively including source/drain features disposed on opposing sides of a first gate structure; dummy transistor devices disposed in the dummy device region and respectively including dummy source/drain features disposed on opposing sides of a second gate structure; and a conductive path formed by a conductive structure or conductive structures directly over and isolated from the dummy transistor devices in the dummy region.

In certain embodiments, the semiconductor structure further includes a contact etch stop layer located directly over the dummy transistor devices in the dummy region and located directly under the conductive structures.

In certain embodiments of the semiconductor structure, the contact etch stop layer is a nitride-rich layer.

In certain embodiments of the semiconductor structure, the conductive structures include at least one conductive contact located over the dummy transistor devices and at least one conductive via located over the conductive contact.

In certain embodiments, the semiconductor structure further includes a metallization layer over the conductive structures, and the metallization layer is electrically connected to the conductive structures.

In certain embodiments, the semiconductor structure further includes a second conductive path formed by a second conductive structure or structures directly over electrically connected to the transistor devices in the device region. In certain embodiments of the semiconductor structure, the metallization layer is electrically connected to the second conductive structures.

In certain embodiments of the semiconductor structure, the conductive path has a selected resistance.

In another embodiment, a method includes simultaneously forming a first transistor device in a device region of a substrate and a second transistor device in a dummy region of the substrate; isolating the second transistor device under a structure; and simultaneously forming a first conductive path in electrical connection with the first transistor device in the device region and forming a second conductive path isolated from the second transistor in the dummy region.

In certain embodiments of the method, the structure is an etch stop layer formed over the second transistor device, and the etch stop layer is not located over the first transistor in the device region.

In certain embodiments of the method, the second conductive path is formed by a second conductive contact formed on the etch stop layer and a second conductive via formed on the second conductive contact.

In certain embodiments of the method, the structure is a dielectric layer formed over the first transistor device and over the second transistor device.

In certain embodiments of the method, the second conductive path is formed by a second conductive via formed over the dielectric layer.

In certain embodiments of the method, the first conductive path is formed by a first conductive contact formed in the dielectric layer and a first conductive via formed over the first conductive contact.

In another embodiment, a method includes forming a transistor device over a substrate; determining a desired resistance of a conductive path over and isolated from the transistor device; designing a structure of the conductive path with the desired resistance; isolating the transistor device under a structure; and forming a conductive path isolated from the transistor device, wherein the conductive path is formed with the structure and has the desired resistance.

In certain embodiments of the method, isolating the transistor device under the structure includes forming a contact etch stop layer over the transistor device.

In certain embodiments of the method, forming the conductive path includes forming a conductive contact over the contact etch stop layer and forming a conductive via electrically connected to the conductive contact.

In certain embodiments of the method, isolating the transistor device under the structure includes forming a dielectric layer over the transistor device.

In certain embodiments of the method, forming the conductive path includes forming a conductive via over the dielectric layer.

In certain embodiments of the method, forming the conductive path isolated from the transistor device includes forming at least three conductive paths isolated from the transistor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a substrate comprising a device region and a dummy region;
transistor devices disposed in the device region and respectively comprising source/drain features disposed on opposing sides of a first gate structure;
dummy transistor devices disposed in the dummy region and respectively comprising dummy source/drain features disposed on opposing sides of a second gate structure; and
a conductive path formed by a conductive structure or conductive structures directly over and isolated from the dummy transistor devices in the dummy region.

2. The semiconductor structure of claim 1, further comprising a contact etch stop layer located directly over the dummy transistor devices in the dummy region and located directly under the conductive structures.

3. The semiconductor structure of claim 2, wherein the contact etch stop layer is a nitride layer.

4. The semiconductor structure of claim 2, wherein the conductive structures comprise at least one conductive contact located over the dummy transistor devices and at least one conductive via located over the conductive contact.

5. The semiconductor structure of claim 4, further comprising a metallization layer over the conductive structures, wherein the metallization layer is electrically connected to the conductive structures.

6. The semiconductor structure of claim 5, further comprising a second conductive path formed by a second conductive structure or structures directly over electrically connected to the transistor devices in the device region.

7. The semiconductor structure of claim 6, wherein the metallization layer is electrically connected to the second conductive structure.

8. The semiconductor structure of claim 1, wherein the conductive path has a selected resistance.

9. A method comprising:
simultaneously forming a first transistor device in a device region of a substrate and a second transistor device in a dummy region of the substrate;
isolating the second transistor device under a structure; and
simultaneously forming a first conductive path in electrical connection with the first transistor device in the device region and forming a second conductive path isolated from the second transistor device in the dummy region.

10. The method of claim 9, wherein the structure is an etch stop layer formed over the second transistor device, wherein the etch stop layer is not located over the first transistor device in the device region.

11. The method of claim 10, wherein the second conductive path is formed by a second conductive contact formed on the etch stop layer and a second conductive via formed on the second conductive contact.

12. The method of claim 9, wherein the structure is a dielectric layer formed over the first transistor device and over the second transistor device.

13. The method of claim 12, wherein the second conductive path is formed by a second conductive via formed over the dielectric layer.

14. The method of claim 13, wherein the first conductive path is formed by a first conductive contact formed in the dielectric layer and a first conductive via formed over the first conductive contact.

15. A method comprising:
forming a transistor device over a substrate;
determining a desired resistance of a conductive path over and isolated from the transistor device;
designing a structure of the conductive path with the desired resistance;
isolating the transistor device under a structure; and
forming a conductive path isolated from the transistor device, wherein the conductive path is formed with the structure and has the desired resistance.

16. The method of claim 15, wherein isolating the transistor device under the structure comprises forming a contact etch stop layer over the transistor device.

17. The method of claim 16, wherein forming the conductive path comprises forming a conductive contact over the contact etch stop layer and forming a conductive via electrically connected to the conductive contact.

18. The method of claim 15, wherein isolating the transistor device under the structure comprises forming a dielectric layer over the transistor device.

19. The method of claim 18, wherein forming the conductive path comprises forming a conductive via over the dielectric layer.

20. The method of claim 15 wherein forming the conductive path isolated from the transistor device comprises forming at least three conductive paths isolated from the transistor device.
